(19) United States
(12) Patent Application Publication
(10) Pub. No.: US 2015/0033546 A1
(43) Pub. Date: Feb. 5, 2015

(54) DRIVING APPARATUS, CHARGED PARTICLE BEAM IRRADIATION APPARATUS, AND METHOD OF MANUFACTURING DEVICE

(71) Applicant: CANON KABUSHIKI KAISHA, Tokyo (JP)

(72) Inventor: Shinji Uchida, Utsunomiya-shi (JP)

(21) Appl. No.: 14/444,774

(22) Filed: Jul. 28, 2014

(30) Foreign Application Priority Data
Jul. 31, 2013 (JP) 2013-159137

(51) Int. Cl. H01F 7/06; G21K 5/02; H01J 37/30

(52) U.S. Cl. CPC H01F 7/06; H01J 37/30; G21K 5/02
USPC 29/602.1; 335/219; 250/492.3

(57) ABSTRACT

A driving apparatus includes an electromagnetic actuator configured to generate a motive power by an electromagnetic force; movable portions configured to be moved by the electromagnetic actuator, and a magnetic shield unit including a first magnetic shield and a second magnetic shield that surround the electromagnetic actuator in this order, and from a side closer to a magnetic field generating portion of the electromagnetic actuator.

An opening through which a demagnetizing coil penetrates provided on at least one of the magnetic shields is opposite to the first magnetic shield or the second magnetic shield in a part of the area of the opening.

### BACKGROUND OF THE INVENTION

1. Field of the Invention

This disclosure relates to a driving apparatus, a charged particle beam irradiation apparatus, and a method of manufacturing a device.

2. Description of the Related Art

It is preferable not to arrange a magnetized object in the periphery of an apparatus susceptible to a magnetic field. For example, in the case of a drawing apparatus 100, there is a problem that a drawing position of a pattern is deviated due to an influence of an external magnetic field generating from an electromagnetic actuator or the like for driving a substrate.

Therefore, Japanese Patent Laid-Open No. 2004-153151 discloses a technology that reduces a leakage of the magnetic field generating from the electromagnetic actuator by surrounding the electromagnetic actuator with a plurality of magnetic shields formed of hollow members. Japanese Patent Laid-Open No. 2007-311457 discloses a technology that reduces the leakage of the magnetic field by flowing an alternating current to a demagnetizing coil and reducing the magnitude of the current gradually.

Application of the technology disclosed in Japanese Patent Laid-Open No. 2004-153151 has an effect of reducing the influence of the magnetic field generating from the electromagnetic actuator. However, in a case where a stress is applied to the magnetic shield when the magnetic shield is subject to impact due to an emergency stop of a driving apparatus, the magnetic shield is magnetized. The magnetic shield may be magnetized also in a case where a stress is applied to the magnetic shield by a high-speed driving of the driving apparatus.

Even when the technology disclosed in Japanese Patent Laid-Open No. 2007-311457 is applied to the electromagnetic actuator surrounded by the plurality of magnetic shields, an opening needs to be formed in the magnetic shields for mounting a demagnetizing coil to the magnetic shield. Therefore, the leakage of the magnetic field may be caused by the position of the opening of the magnetic shield.

### SUMMARY OF THE INVENTION

Therefore, this disclosure provides a driving apparatus configured to be capable of reducing an influence of magnetization of a magnetic shield.

This disclosure includes an electromagnetic actuator; a movable portion configured to be moved by the electromagnetic actuator; a magnetic shield unit including a first magnetic shield and a second magnetic shield that surround the electromagnetic actuator in this order, and from a side closer to a magnetic field generating portion of the electromagnetic actuator; and a demagnetizing coil penetrating through an opening provided in at least one of the first magnetic shield and the second magnetic shield, and is characterized in that the opening through which the demagnetizing coil penetrates is opposite to the first magnetic shield or the second magnetic shield in at least part of an area of the opening.

Further features of the present invention will become apparent from the following description of exemplary embodiments with reference to the attached drawings.

### BRIEF DESCRIPTION OF THE DRAWINGS

FIG. 1 is a drawing illustrating a configuration of a drawing apparatus on which a driving apparatus of a first embodiment is mounted.

FIG. 2 is a cross-sectional view of the driving apparatus of the first embodiment.

FIG. 3 is a cross-sectional view of the driving apparatus of a second embodiment.

FIG. 4 is an appearance view of the driving apparatus of a third embodiment.

FIG. 5 is a cross-sectional view of the driving apparatus of a fourth embodiment.

### DESCRIPTION OF THE EMBODIMENTS

A driving apparatus of this disclosure is an apparatus on which the driving apparatus is mounted, and may be applied to an apparatus being susceptible to an external magnetic field. Examples of such an apparatus include a drawing apparatus 100, instruments using charged particle beam such as an electronic microscope (charged particle beam irradiation apparatus), and medical instruments such as a brain magnetic field measurement device configured to measure brain functions of a test subject by detecting a change of a magnetic field.

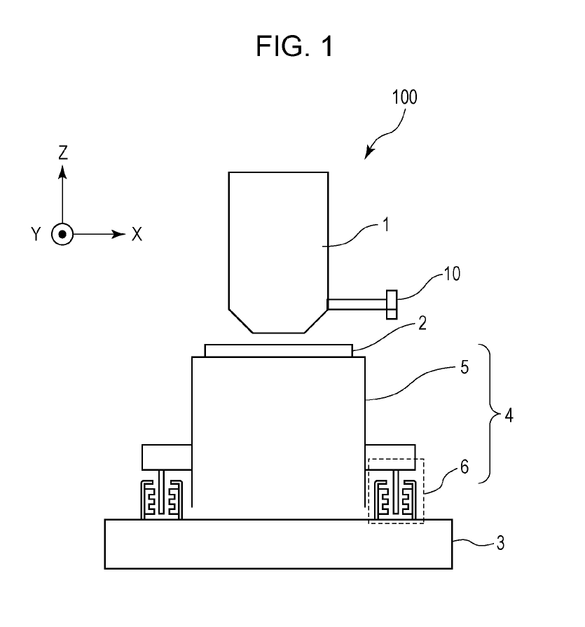

FIG. 1 is a drawing illustrating a schematic configuration of the drawing apparatus 100 on which a driving apparatus 6 of a first embodiment is mounted. The drawing apparatus 100 in FIG. 1 is assumed to be capable of mounting driving apparatuses of respective embodiments described later instead of the driving apparatus 6 of the first embodiment. The drawing apparatus 100 includes a housing 1, a substrate 2 (irradiation target), a long stroke stage 3, and a short stroke stage 4. The housing 1 accommodates an electron source (not illustrated) and an electronic optical system (not illustrated) for radiating an electron beam toward the substrate 2.

The short stroke stage 4 includes a supporting member 5 (movable object) on which the substrate 2 is mounted and the driving apparatus 6 configured to provide the supporting member 5 with a driving force. The short stroke stage 4 is placed on an upper surface of the long stroke stage 3. The long stroke stage 3 is configured to position the substrate 2 roughly by a driving device, which is not illustrated, mounted on the long stroke stage 3. In contrast, the supporting member 5 of the short stroke stage 4 is configured to position the substrate 2 precisely by moving the substrate 2 by using the driving apparatus 6 by a short stroke.

A substrate holder (not illustrate) for holding the substrate 2 and a mirror (not illustrated) used for measuring the position of the supporting member 5 are installed on the supporting member 5. By reflecting a laser beam emitted by a laser interferometer (not illustrated) with the mirror, positions of the supporting member 5 in X, Y, and Z axis directions are measured. The long stroke stage 3 and the supporting member 5 of the short stroke stage 4 are driven on the basis of the measured positional information. An intended pattern is drawn on the substrate 2 by irradiating the substrate 2 with the electron beam while driving the supporting member 5 in this manner.

In order to measure the magnitude of the magnetic field in the periphery of the driving apparatus 6, a magnetic sensor 10 is provided in the housing 1. However, the position of the magnetic sensor 10 is not limited to a side surface of the housing 1 as illustrated in FIG. 1, and may be arranged at other positions. A plurality of the magnetic sensors 10 may be arranged as well. A flux-gate type magnetic sensor is preferably used as the magnetic sensor 10. It is because that the flux-gate type magnetic sensor has a high-sensitivity and a high-resolution performance and is relatively compact among the magnetic sensors that can be used under the room temperature.

In a case where the magnetic sensor 10 detects the magnetic field already before irradiating the electron beam, the corresponding value is determined as an offset value. In this configuration, when a magnetic shield or the like described later which constitutes the driving apparatus 6 is magnetized, the magnetization can be detected.

The drawing apparatus 100 having the configuration described above is installed in a vacuum chamber (not illustrated) having a vacuum internal atmosphere. Then, the vacuum chamber is installed in a magnetic shielding room (not illustrated) to avoid an influence of the magnetic field from peripheral instruments such as an electric component rack (not illustrated) including a control substrate for controlling the electron beam.

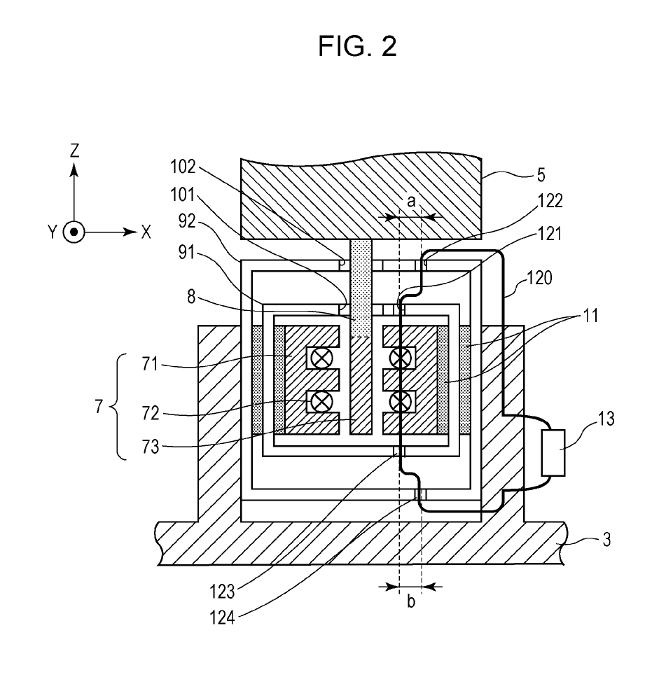

FIG. 2 is a cross-sectional view of the driving apparatus 6 of the first embodiment. An electromagnet unit 7 is mounted as an electromagnetic actuator for driving the supporting member 5 with an electromagnetic force.

The electromagnet unit 7 includes an E-core 71 as a stator and an I-core 73 as a mover, both formed of a magnetic material. The electromagnet unit 7 further includes an exciting coil 72 configured to excite the E-core 71, and the I-core 73 moves upon reception of a magnetic attraction force generated between the I-core 73 and the excited E-core 71.

The intensity and the direction of the magnetic attraction force generated between the E-core 71 and the I-core 73 is controlled by controlling the magnitude and the direction of a current flowing in the exciting coil 72. In order to achieve a reduction in weight of a movable portion of the short stroke stage 4, the I-core 73 is preferably lighter than the E-core 71. A merit of using the electromagnet unit 7 as the electromagnetic actuator is, for example, a superior efficiency of isolating a thrust per unit current.

A transmitting member 8 is coupled at one end to the I-core 73 and at the other end to the supporting member 5. Therefore, when the I-core 73 is moved upon reception of the magnetic attraction force, the supporting member 5 moves in conjunction with the I-core 73 via the transmitting member 8. In a case where the electromagnet unit 7 is arranged as illustrated in FIG. 2, the supporting member 5 moves in the X-axis direction. The transmitting member 8 is preferably a non-magnetic material for preventing a leakage of a magnetic field.

The driving apparatus 6 drives an object coupled to a movable portion via the movable portion which is movable by an electromagnetic force generated by the electromagnetic actuator. In other words, in the first embodiment and second to fourth embodiments described later, the I-core 73 and the transmitting member 8 correspond to the movable portions. The supporting member 5 may be moved in six axes directions by mounting driving apparatus configured to move in the Y-axis and Z-axis direction, which is not illustrated, in addition to the driving apparatus 6 configured to move the supporting member 5 in the X-axis direction illustrated in FIG. 2 on the drawing apparatus 100 in FIG. 1.

In order to reduce a leakage of the magnetic field generating from the electromagnet unit 7, the electromagnet unit 7 is multiply surrounded by a plurality of the magnetic shields (the magnetic shield unit). The magnetic shield has a hollow parallelepiped shape (hexahedron) shape. A magnetic shield (first magnetic shield) 91 having an opening 121 and a magnetic shield (second magnetic shield) 92 having an opening 123 are provided in the order from a magnetic field generating portion of the electromagnet unit 7, that is, from the side closer to the E-core 71 in the first embodiment.

As a material of the magnetic shields 91 and 92, a soft magnetic material such as Permalloy is used. The soft magnetic material includes materials having a high magnetic permeability, and includes materials superior in shielding performance that traps the magnetic field in a closed space thereby.

In order to fix and integrate the magnetic shields 91 and 92 and the E-core 71, the magnetic shield 91 and the magnetic shield 92, and the magnetic shield 91 and the E-core 71 are adhered respectively to each other by an epoxy-based adhesive agent 11. However, the method of fixing and integrating the magnetic shields 91 and 92 and the E-core 71 is not limited thereto, and what is essential is just to resist magnetization.

An opening 101 is provided in the magnetic shield 91 and an opening 102 is provided in the magnetic shield 92 so as to allow non-contact penetration of the transmitting member 8 coupled to the I-core 73 therethrough. The thrust generated by the electromagnet unit 7 may be transmitted to the supporting member 5 by the transmitting member 8 penetrating through the openings 101 and 102.

The magnetic shield 91 is further provided with the opening 121 and the opening 123. The magnetic shield 92 is further provided with an opening 122 and an opening 124. The openings 121 to 124 are openings for allowing penetration of a demagnetizing coil 120 for demagnetizing the magnetism of the magnetic shield therethrough in a case where the magnetic shield is magnetized. The demagnetizing coil 120 may come into contact with the openings 121 to 124. The openings 121 to 124 are preferably as small as possible in order to reduce the leakage of the magnetic field. For example, the diameter is not larger than 1 mm, more preferably, on the order to 0.1 mm.

In order to prevent the magnetic field generating from the electromagnet unit 7 from leaking via the openings 121 to 124, the opening 122 is arranged so as to be shifted from the opening 121 by a and the opening 124 is arranged so as to be shifted from the opening 123 by b in the X-axis direction. In this manner, at least part of the area of the opening 121 and the opening 123 of the magnetic shield 91 is opposite to the magnetic shield 92, so that the magnetic field leaked through the opening 121 and the opening 123 may be shielded by the magnetic shield 92.

The area opposing the magnetic shield 92 is preferably larger than the area that the opening 121 is opposite to the opening 122 and the area that the opening 123 is opposite to the opening 124 as much as possible. Further preferably, the opening 121 and the opening 123 oppose only the magnetic shield 92.

The shift width a and the shift width b are determined considering an area to be demagnetized and an influence of the magnetic field in the periphery of the substrate 2 on an orbit of the electron beam at the time of drawing. The opening 123 and the opening 124 are apart from the substrate 2 more than the opening 121 and the opening 122. In other words, an influence of the magnetic field leaking from the opening 123 and the opening 124 on a phenomenon of positional deviation of drawing on the substrate 2 by the electron beam is smaller. Therefore, as regards the shift width a and the shift width b of the opening, a is preferably larger than b.

The demagnetizing coil 120 is connected to a current source 13. In a case magnetization of the driving apparatus 6 is sensed by the electromagnetic sensor 10, an alternating current is made to flow to the demagnetizing coil 120 by using the current source 13. The alternating current is made to flow by a magnitude that saturates the magnetized magnetism, so that the magnetic field in the periphery of the demagnetizing coil 120 can be reduced by reducing the magnitude (amplitude) of the alternating current gradually toward zero.

For example, in FIG. 2, when the alternating current is made to flow to the demagnetizing coil 120, an alternating magnetic field which penetrates through the area surrounded by the demagnetizing coil 120 in the Y-axis direction and circulates around the demagnetizing coil 120 is generated. Accordingly, the magnetism in the area surrounded by the demagnetizing coil 120 and the peripheral area thereof may be reduced.

Measurement by the magnetic sensor 10 and demagnetization by the demagnetizing coil 120 are performed when drawing with the electron beam is not performed. For example, measurement by the magnetic sensor 10 and demagnetization by the demagnetizing coil 120 are performed every time when drawing on one substrate or a plurality of substrates in one lot has terminated. If measurement by the magnetic sensor 10 or demagnetization by the demagnetizing coil 120 is performed during irradiation of the substrate 2 with the electron beam, the magnetic field generating from the demagnetizing coil 120 may bend the orbit of the electron beam. If the operation that is subject to the influence of the magnetic field is not performed, a demagnetizing operation may be performed in parallel to other operations such as moving the driving apparatus 6.

By forming the openings 121 to 124 in the magnetic shields 91 and 92 and placing the demagnetizing coil 120 therethrough, in a case where the magnetization of the magnetic shields 91 and 92 is sensed, demagnetization can be performed as-is without demounting the driving apparatus 6 from the vacuum chamber. In addition, by arranging at least part of the area of the openings 121 and 123 so as to oppose the magnetic shield 92, leakage of the magnetic field generating from the electromagnet unit 7 may be reduced, so that lowering of pattern drawing accuracy on the substrate 2 may be reduced.

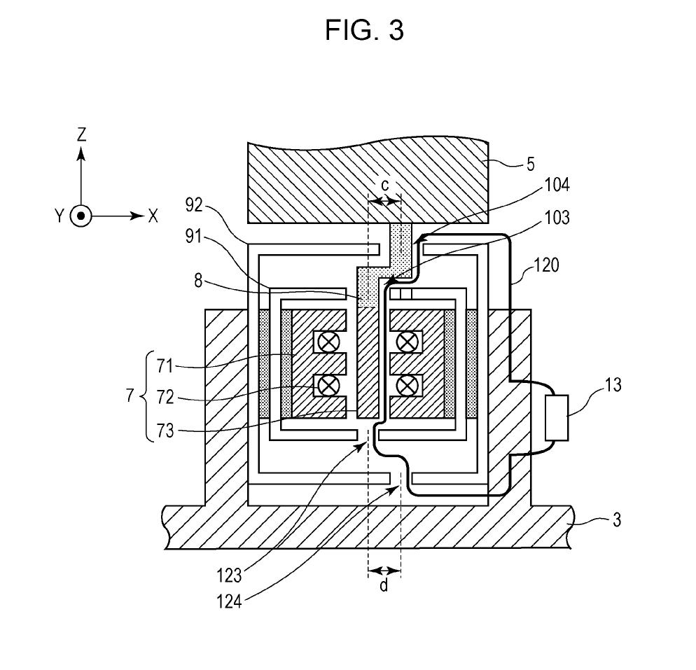

A configuration of the driving apparatus 6 of the second embodiment is illustrated in FIG. 3. The second embodiment is a mode in which the opening 103 of the magnetic shield 91 and the opening 104 of the magnetic shield 92 through which the transmitting member 8 penetrates are used also as the opening 121 and the opening 122 of the first embodiment.

The effect of the demagnetization is obtained by generating the magnetic field symmetrically from the demagnetizing coil 120, so that the effect of the demagnetization is reduced as the opening which allows penetration of the demagnetizing coil 120 is arranged less symmetrically. Therefore, in order to demagnetize the magnetism that the driving apparatus 6 magnetizes, the configuration of the second embodiment in which the demagnetizing coil 120 passes through a portion near a center portion of the electromagnet unit 7 is preferable.

In addition, by reducing the two openings for the demagnetizing coil 120 to be provided in the magnetic shields 91 and 92, not only the same demagnetizing effect as the first embodiment is obtained, but also the reduction of the magnetic field leaking from the magnetic shield 92 is achieved.

A case where only one of the opening 103 and the opening 104 through which the transmitting member 8 penetrates is shared and the opening for the demagnetizing coil 120 is formed in one of the magnetic shields 91 and 92 through which the transmitting member 8 penetrates is also applicable. If the opening through which the demagnetizing coil 120 penetrates is opposite to the magnetic shield 91 or the magnetic shield 92, the magnetic field leaking from the magnetic shield 92 may be reduced.

Furthermore, by shifting the openings 103 and 104 through which the transmitting member 8 penetrates by c in the X-axis direction to cause the opening 103 to oppose the magnetic shield 92, the magnetic field leaking via the opening 103 and the opening 104 may be reduced. In the same manner, by arranging the opening 123 and the opening 124 so as to be shifted by d in the X-axis direction to cause the opening 123 to oppose the magnetic shield 92, the magnetic field leaking via the opening 123 and the opening 124 may be reduced. In the case of the second embodiment, the transmitting member 8 has a bent shape so as to be capable of penetrating through the openings 103 and 104 shifted in position in the X-axis direction.

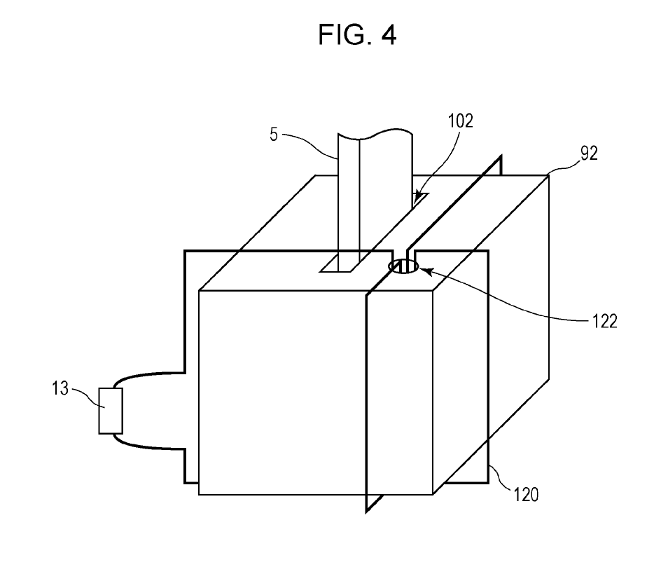

In the third embodiment, one demagnetizing coil 120 is wound a plurality of times on the driving apparatus 6. An appearance of the driving apparatus 6 of the third embodiment is illustrated in FIG. 4. In FIG. 4, the demagnetizing coil 120 is wound around the magnetic shield 92 of the driving apparatus 6 by four times so as to extend along respective surfaces thereof. The current source 13 is connected to the demagnetizing coil 120. The demagnetizing method is the same as the first and the second embodiments.

In the third embodiment, the demagnetizing coil 120 is wound on the front, rear, left, and right of the driving apparatus 6. By winding the demagnetizing coil 120 in this manner, an effect that the magnetism that the driving apparatus 6 magnetizes can be demagnetized entirely is achieved. Furthermore, by the demagnetizing coil 120 wound in series a plurality of times, a demagnetizing effect per unit current is advantageously increased.

FIG. 4 illustrates a state in which the demagnetizing coil 120 penetrates through one hole of the magnetic shield 92 four times. In the case of the magnetic shield 91 inside the magnetic shield 92 as well, the demagnetizing coil 120 may penetrate through one opening of the magnetic shield 91 a plurality of times or may penetrate through different openings. However, the magnetic field leaking from the magnetic shield 92 may be reduced by arranging either a pair of the opening 121 and the opening 122 or a pair of the opening 123 and the opening 124 so as to be shifted from the other pair in either the X-, Y-, or Z-axis direction.

In the third embodiment, the demagnetizing coil 120 wound by four times has been exemplified. However, the demagnetizing coil 120 may be wound more than four times. The more times the demagnetizing coil is wound, the larger the magnetic field generating per unit current becomes. Therefore, the magnitude of the current required for demagnetization may be reduced.

Furthermore, the demagnetizing coil 120 may be formed to constitute a parallel circuit including a plurality of closed circuits as a modification of the third embodiment. In this case, a voltage required for providing a current may be reduced.

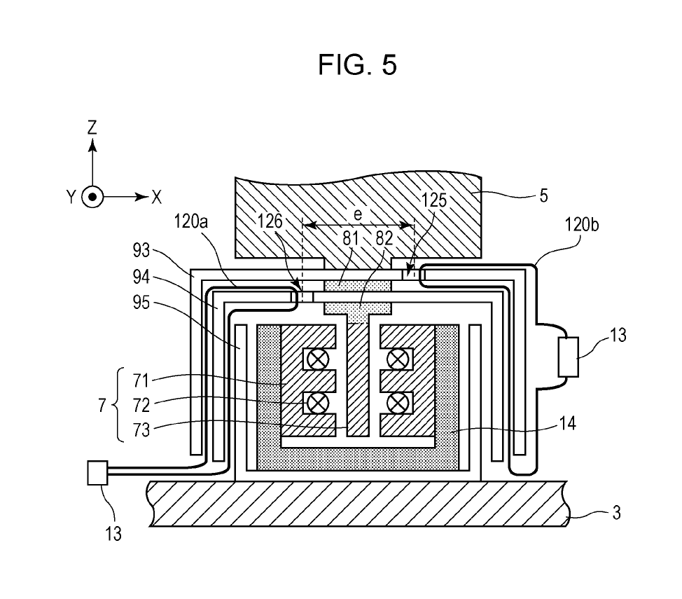

The configuration of the driving apparatus 6 of the fourth embodiment is illustrated in FIG. 5. The fourth embodiment is different from other embodiments in shape of magnetic shields 93, 94, and 95 and arrangement of the demagnetizing coil 120. In the hollow parallelepiped, the magnetic shield is not provided on one surface thereof, and leakage of the magnetic field generating from the electromagnet unit 7 is reduced by combining the magnetic shields 93, 94, and 95 having different sizes. In addition, in order to avoid the E-core 71 from coming into contact with a magnetic shield 95 while fixing the E-core 71, a non-magnetic member 14 is placed on the magnetic shield 95, and the E-core 71 is fixed by the non-magnetic member 14.

The supporting member 5 is integrally coupled to the magnetic shields 93 and 94, transmitting members 81 and 82, and the I-core 73. By the thrust generated from the I-core 73, I core and the above-described members coupled thereto are driven.

The demagnetizing coil 120 includes a demagnetizing coil 120b penetrating through an opening 125 of the magnetic shield 93, and a demagnetizing coil 120a penetrating through an opening 126 of the magnetic shield 94. The opening 126 closer to the electromagnet unit 7 is opposite to the magnetic shield 93. With such an arrangement, leakage of the magnetic field generating from the electromagnet unit 7 may be reduced.

In addition, as illustrated in FIG. 5, the demagnetizing coils 120a and 120b which constitute different closed circuits may be penetrated through different openings, respectively. Demagnetization of the entire driving apparatus 6 is enabled by arranging the demagnetizing coil 120 symmetrically as in the fourth embodiment.

In the fourth embodiment as well, the opening 125 and the opening 126 are arranged by being shifted by e in the X-axis direction. Accordingly, the driving apparatus 6 capable of reducing the leakage of the magnetic field while demagnetizing the magnetism that the magnetic shields 91 and 92 magnetize is obtained.

Finally, other embodiments will be described. In the first to the fourth embodiments, examples in which only the transmitting member 8 penetrates through the openings formed in the magnetic shields 91 and 92 have been described. However, this disclosure is not limited thereto. What is essential is that the movable portion which can be moved by the electromagnetic actuator penetrates through the openings, and for example, a configuration in which an I core 73 penetrates through the openings is also applicable.

Portions which can be moved by the electromagnetic actuator like the I-core 73 and the transmitting member 8 do not necessarily have to be configured by being combined with different materials, and may be integrally formed by using the same material. The costs required for assembly may be reduced by forming integrally.

In cross-sectional views of the driving apparatus 6 in FIGS. 2, 3, and 5, the case where the openings through which the demagnetizing coil 120 penetrates are shifted in the X-direction is illustrated. However, the openings may be shifted in other directions (directions having a component in the Y-direction or components in the X-axis and the Y-axis directions).

Even in a case where the magnetic sensor 10 detects magnetization, if the value is not larger than a tolerance, setting not to execute demagnetization is also possible.

A linear motor unit may be mounted as the electromagnetic actuator instead of the electromagnet unit 7. The shape of the magnetic shield is not limited to the hollow parallelepiped, and may be a magnetic shield having a curved surface, or may be a combination of a magnetic shield having a parallelepiped shape and a magnetic shield having a curved surface.

Although the configuration of the two-layered magnetic shield is illustrated, configurations of three- or more-layered magnetic shield are also applicable. The shielding ratio of the magnetic field depends on the thicknesses of the magnetic shields 91 and 92 and the distance between the magnetic shields. Therefore, the configuration may be determined in view of these elements. However, in the case where the driving apparatus 6 is configured by using the three- or more-layered magnetic shield and in the case where the demagnetizing coil 120 is wound one time, the demagnetizing coil 120 preferably penetrates through the magnetic shield closer to the electromagnet unit 7 as much as possible. The reason is that when symmetric property of the magnetic field generated by the demagnetizing coil 120 is considered, biasing of distribution of the magnetic field to be generated for demagnetization is reduced if the demagnetizing coil 120 exists in the vicinity of the center of the driving apparatus 6.

An arrangement of the demagnetizing coil 120 for demagnetizing the magnetism of the magnetic shields 91 and 92 and the openings for allowing the demagnetizing coil 120 to penetrate therethrough has been described thus far. By the arrangement such that at least part of the area of the opening of the magnetic shield 91 is opposite to the magnetic shield 92, an effect that the magnetism that the magnetic shields 91 and 92 magnetize can be demagnetized is obtained and also the magnetic field leaked from the openings for the demagnetizing coil 120 may be reduced.

Accordingly, a desired pattern may be drawn on the substrate 2 by irradiation of the electron beam without being subject to the influence of leakage of the magnetic field generating from the electromagnetic actuator or the magnetism that the magnetic shields 91 and 92 magnetize.

### Method of Manufacturing Device

A method of manufacturing a device of this disclosure includes a process of irradiating a substrate on a supporting member with charged particle beam while moving the supporting member by the driving apparatus described in the respective embodiments, and a process of developing the substrate 2 on which a pattern is drawn. Furthermore, other known processes (oxidization, film formation, depositing, doping, flattening, etching, resist separation, dicing, bonding, packaging, and the like) may be included.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-159137, filed Jul. 31, 2013 which is hereby incorporated by reference herein in its entirety.

What is claimed is:

1. A driving apparatus comprising:
an electromagnetic actuator;
a movable portion configured to be moved by the electromagnetic actuator;
a magnetic shield unit including a first magnetic shield and a second magnetic shield that surround the electromagnetic actuator in this order, and from a side closer to a magnetic field generating portion of the electromagnetic actuator; and
a demagnetizing coil penetrating through an opening provided in at least one of the first magnetic shield and the second magnetic shield, wherein
the opening through which the demagnetizing coil penetrates is opposite to the first magnetic shield or the second magnetic shield in at least a part of an area of the opening.

2. The driving apparatus according to claim 1, wherein
the opening through which the demagnetizing coil penetrates is opposite to the first magnetic shield or the second magnetic shield in a part of the area of the opening so a leakage of a magnetic field from the opening of the second magnetic shield is reduced.

3. The driving apparatus according to claim 1, wherein
an alternating current flows in the demagnetizing coil so that a magnetism that at least one of the first and second magnetic shields magnetizes is reduced.

4. The driving apparatus according to claim 1, wherein
an area of the opening through which the demagnetizing coil penetrates is opposite to the first magnetic shield or the second magnetic shield, the area is larger than an area of the opening opposing an opening of the first magnetic shield or the second magnetic shield.

5. The driving apparatus according to claim 1, wherein
the opening through which the demagnetizing coil penetrates is opposite to only the first magnetic shield or the second magnetic shield.

6. The driving apparatus according to claim 1, wherein
in a case where the first magnetic shield unit includes at least three magnetic shields and the first magnetic shield is the magnetic shield closest to the electromagnetic actuator.

7. The driving apparatus according to claim 1, wherein
the opening through which the demagnetizing coil penetrates is shared with at least one of the openings through which the movable portion penetrates.

8. The driving apparatus according to claim 1, wherein
the demagnetizing coil penetrates through the opening of at least one of the first magnetic shield and the second magnetic shield a plurality of times.

9. The driving apparatus according to claim 1, wherein
the demagnetizing coil constitutes a parallel circuit.

10. The driving apparatus according to claim 1, wherein
the magnetic shield is a hexahedron and the demagnetizing coil is arranged so as to extend along respective surfaces of the hexahedron.

11. A charged particle beam irradiation apparatus for irradiating an irradiation target on a movable object with charged particle beam comprising:
the movable object;
and
a driving apparatus configured to provide a driving force to the object, wherein
the driving apparatus includes:
an electromagnetic actuator;
a movable portion moved by the electromagnetic actuator;
a magnetic shield unit including a first magnetic shield and a second magnetic shield that surround the electromagnetic actuator from a side closer to a magnetic field generating portion of the electromagnetic actuator in this order; and
a demagnetizing coil penetrating through an opening provided in at least one of the first magnetic shield and the second magnetic shield, wherein
the opening through which the demagnetizing coil penetrates is opposite to the first magnetic shield or the second magnetic shield in a part of an area of the opening.

12. A method of manufacturing a device comprising:
irradiating a substrate as an irradiation target with charged particle beam by using a driving apparatus; and
developing the substrate irradiated in the irradiating, wherein
the driving apparatus includes:
an electromagnetic actuator;
a movable portion configured to be moved by the electromagnetic actuator;
a magnetic shield unit including a first magnetic shield and a second magnetic shield that surround the electromagnetic actuator from a side closer to a magnetic field generating portion of the electromagnetic actuator in this order; and
a demagnetizing coil penetrating through an opening provided in at least one of the first magnetic shield and the second magnetic shield, wherein
the opening through which the demagnetizing coil penetrates is opposite to the first magnetic shield or the second magnetic shield in at least a part of the area of the opening.
